(19) United States
(12) Patent Application Publication
(10) Pub. No.: US 2013/0285673 A1
(43) Pub. Date: Oct. 31, 2013

(54) SYSTEM AND METHOD FOR LOW VOLTAGE DIFFERENTIAL SIGNALING TEST

(71) Applicants: Xiaodong Han, Shenzhen (CN); Yi Zhou, Shenzhen (CN); Tao Hu, Tianjin (CN); Ching Brendon Chau, Millbrae, CA (US)

(72) Inventors: Xiaodong Han, Shenzhen (CN); Yi Zhou, Shenzhen (CN); Tao Hu, Tianjin (CN); Ching Brendon Chau, Millbrae, CA (US)

(73) Assignee: NVIDIA CORPORATION, Santa Clara, CA (US)

(21) Appl. No.: 13/548,080

(22) Filed: Jul. 12, 2012

(30) Foreign Application Priority Data
Apr. 27, 2012 (CN) 201210129700.1

(51) Int. Cl. G01R 29/00

(52) U.S. Cl. 324/606

(57) ABSTRACT

A test system and method for low voltage differential signaling (LVDS) is provided. The system comprises: an input module for the user to input the information needed by the test; a communication module for connecting the control device 110 and the oscilloscope 120 using the communication means selected by the user; a measurement module for measure the parameters of the LVDS signal thought controlling a oscilloscope; an assessment module for assessing whether the obtained parameters of the LVDS signal comply with relevant LVDS specifications; and an output module for outputting the parameters of the LVDS signal and the assessment result of the parameters from the assessment module. The test system and method for LVDS provided by the present invention can advantageously meet the competitive needs in fast mass production and efficient engineering qualification.

### PRIORITY AND RELATED APPLICATION DATA

The present application claims the priority of Chinese Patent Application No. 201210129700.1, filed on Apr. 27, 2012, which is incorporated herein by reference.

### FIELD

The present disclosure relates generally to signal test systems and methods, and particularly to a test system and method for low voltage differential signaling.

### BACKGROUND

There is often a need to measure various parameters of electrical signals during the manufacture of semiconductor devices. It is desirable to measure parameters of the signals produced by those devices to verify that the devices are operating properly. Information obtained through testing can be used to identify and discard devices that fail to exhibit the expected performance. Test results can sometimes be used to alter the steps in the process used to make the devices. For example, the device can be calibrated in the subsequent steps, so as to meet the expected performance.

As the performance of semiconductor devices has increased, the difficulties of testing those devices have increased. Electronic systems have come to be operated at faster and faster speeds. Also, it has become more prevalent to use low voltage differential signaling (LVDS) for fast signals. LVDS is an electrical signaling system that can transmit differential signals at high data transfer rates with low power consumption, low noises and low costs. Signal characteristics are required to be tested to ensure error free transmission in LVDS.

Currently, LVDS tests are manually performed, which is inefficient and error prone. It cannot meet the competitive needs in fast mass production and efficient engineering qualification. Accordingly, efficiently measuring parameters of fast signals, particularly LVDS signals, is a challenge.

### SUMMARY OF THE INVENTION

The present invention is related to a test system for low voltage differential signaling (LVDS). The system comprises: an input module for the user to input the information needed by the test; a communication module for connecting the control device and the oscilloscope using the communication means selected by the user, a measurement module for measure the parameters of the LVDS signal thought controlling a oscilloscope; an assessment module for assessing whether the obtained parameters of the LVDS signal comply with relevant LVDS specifications; and an output module for outputting the parameters of the LVDS signal and the assessment result of the parameters from the assessment module.

Preferably, the system further comprises a report module for generating a report for the user to read when all the measurements of all the parameters have been finished.

Preferably, the measurement module comprises: a setting module, for setting the oscilloscope; a parameter measurement module for measuring the LVDS signal parameters; and a measurement result obtaining module for transmitting the measurement results of the LVDS signal from the oscilloscope to the test system.

Preferably, the setting module can be further used for: restoring the oscilloscope to the factory settings; locking the oscilloscope: setting the persistence mode; setting the screen capture mode; setting the acquisition mode; selecting a measurement channel; and setting the measurement reference level.

Preferably, the input module comprises a graphic user interface for the user to input the information needed by the test.

Preferably, the communication means is Ethernet or General-Purpose Interface Bus.

Preferably, the information needed by the test comprises the specifications the signal parameters to be tested.

Preferably, the signal parameters comprise the maximum positive peak voltage, the maximum negative peak voltage, peak-peak value, rise time, fall time and jitter.

Preferably, the oscilloscope is an oscilloscope for testing LVDS signals.

Preferably, the report further comprises obtained waveforms of the signals.

In another aspect of the invention, a test method for is also provided. The method comprises: obtaining the information needed by the test; connecting the control device 110 and the oscilloscope 120 using the communication means selected by the user, measuring the parameters of the LVDS signal thought controlling a oscilloscope: assessing whether the obtained parameters of the LVDS signal comply with relevant LVDS specifications; and outputting the parameters of the LVDS signal and the assessment result of the parameters from the assessment module.

Preferably, the method further comprises generating a report for the user to read when all the measurements of all the parameters have been finished.

Preferably, the measuring the parameters of the LVDS signal thought controlling an oscilloscope comprises: setting the oscilloscope; measuring the LVDS signal parameters; and transmitting the measurement results of the LVDS signal from the oscilloscope to the test system.

Preferably, the setting the oscilloscope comprises: restoring the oscilloscope to the factory settings: locking the oscilloscope; setting the persistence mode; setting the screen capture mode; setting the acquisition mode; selecting a measurement channel; and setting the measurement reference level.

Preferably, the obtaining the information needed by the test comprises obtaining the information needed by the test through a graphic user interface.

Preferably, the communication means is Ethernet or General-Purpose Interface Bus.

Preferably, the information needed by the test comprises the specifications the signal parameters to be tested.

Preferably, the signal parameters comprise the maximum positive peak voltage, the maximum negative peak voltage, peak-peak value, rise time, fall time and jitter.

Preferably, the oscilloscope is an oscilloscope for testing LVDS signals.

Preferably, the report further comprises obtained waveforms of the signals.

The test system and method for LVDS provided by the present invention can test the parameters of the LVDS signal quickly and efficiently. It can reduce the possibility of errors in measurement results caused by the operator's mistakes and shorten the average measuring time. Thus, the present invention can advantageously meet the competitive needs in fast mass production and efficient engineering qualification.

Additional features and advantages of the invention will be set forth in the description that follows, and in part will be apparent from the description, or may be learned by practice of the invention. The advantages of the invention will be realized and attained by the structure particularly pointed out in the written description and claims hereof as well as the appended drawings. It is to be understood that both the foregoing general description and the following detailed description are exemplary and explanatory and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 illustrates a block diagram of a test environment 100 for LVDS provided by the present invention in accordance with one embodiment;

FIG. 2 illustrates a block diagram of the LVDS test system 200 in FIG. 1 according to one embodiment of the present invention:

FIG. 3 is a flowchart of one embodiment of an LVDS test method according to one embodiment of the present invention;

FIG. 4 is a flowchart of one embodiment of the parameter measurement step 306 in an LVDS test according to one embodiment of the present invention.

### DETAILED DESCRIPTION

Example embodiments are described herein in the context of a test system and method for low voltage differential signaling. Those of ordinary skill in the art will realize that the following description is illustrative only and is not intended to be in any way limiting. Other embodiments will readily suggest themselves to those skilled in the art having the benefit of this disclosure. Reference will now be made in detail to implementations of the example embodiments as illustrated in the accompanying drawings. The same reference indicators will be used to the extent possible throughout the drawings and the following description to refer to the same or like items.

Reference will now be made in detail to the preferred embodiments of the present invention, examples of which are illustrated in the accompanying drawings.

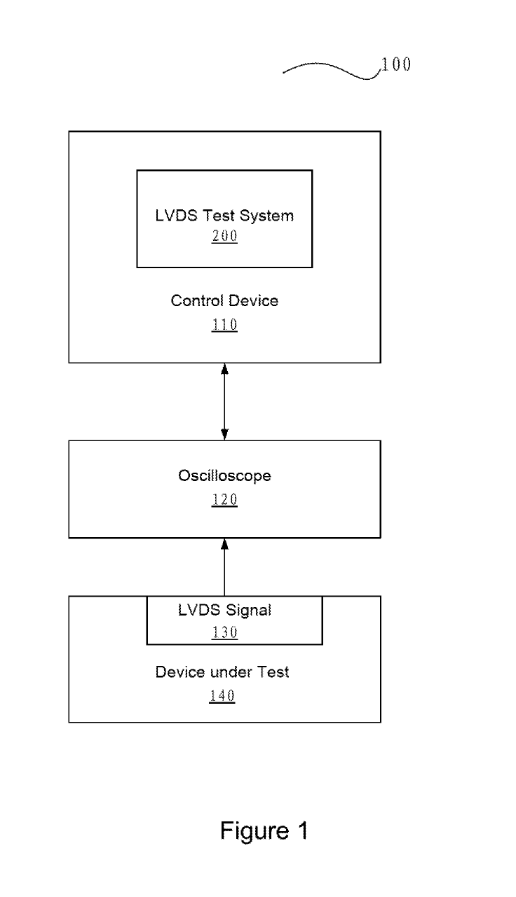

In one aspect of the invention a test system 200 for LVDS test is provided, which can efficiently test the parameters of LVDS signals, such as the maximum positive peak voltage, the maximum negative peak voltage, peak-peak value, rise time, fall time and jitter etc. FIG. 1 illustrates the block diagram of a test environment 100 for LVDS provided by the present invention in accordance with one embodiment. The test environment 100 comprises a control device 110, an oscilloscope 120 and a device under test 140, wherein the control device 110 can be a data processing device or a computing device, such as a personal computer with operating systems, such as Windows 7, and a LVDS test system 200 can be operated on the control device. The control device 110 can be connected to the oscilloscope 120 by communication means, such as Ethernet, General-Purpose Interface Bus (GPIB) and so on. The oscilloscope 120 may be a oscilloscope that can obtain signal waveforms of the LVDS signal 130 by a probe. After the probe obtains the positive signal and the negative signal of the LVDS signal pair and substrate the negative signal from the positive signal, the generated the LVDS signal is transmitted to the oscilloscope 120. In one embodiment, the oscilloscope 120 may be of different models and multiple series produced by Tektronix that can test LVDS signals, such as MSO/DPO5000, DPO7000/C, DPO70000/B/C, DSA70000/B/C and MSO70000/C. The device under test 140 may be an electronic device that generates one or more LVDS signals, such as a circuit board, an electronic device and so on.

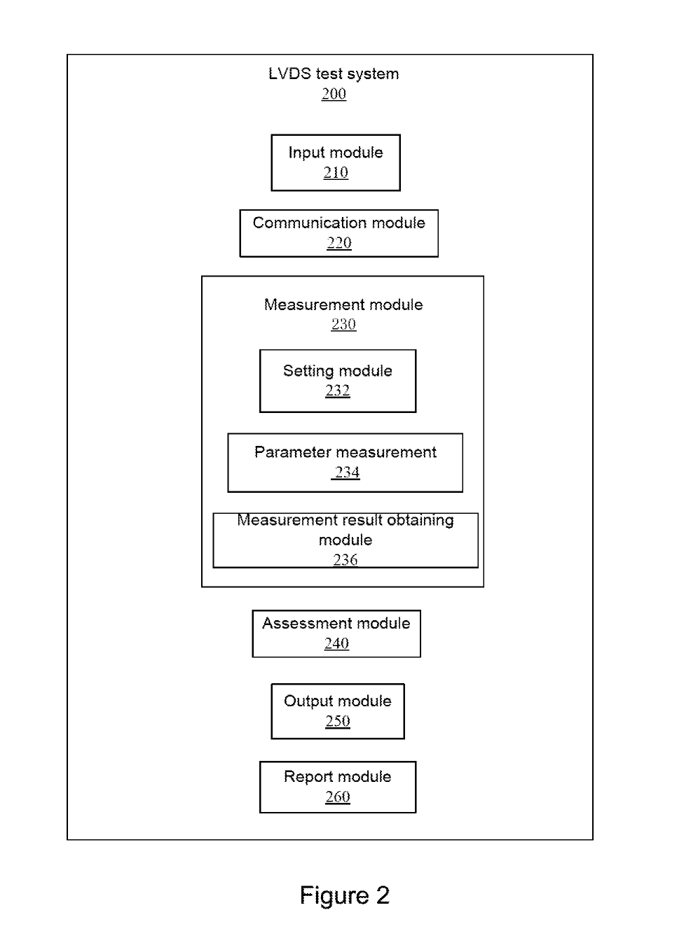

FIG. 2 is a block diagram of the LVDS test system 200 in FIG. 1 according to one embodiment of the present invention. The LVDS test system 200 includes an input module 210, a communication module 220, a measurement module 230, an assessment module 240, an output module 250 and a report module 260.

The input module 210 comprises at least one graphic user interface for the user to input the information needed by the test, such as the product number, the user name, the signal parameters that the user is interested in and the test specifications. In one embodiment, the graphic user interface also provides options for the user to select the communication means, such as Ethernet, General-Purpose Interface Bus (GPIB), to connect the control device 110 and the oscilloscope 120. If the user selects the communication means of Ethernet, the graphic user interface can be used for the user to input the IP address of the oscilloscope 120.

The communication module 220 is configured to connect the control device 110 and the oscilloscope 120 using the communication means selected by the user. If the user selects the communication means of Ethernet, the communication module 220 firstly connects the control device 110 to the oscilloscope 120 using the IP address inputted by the user. If the oscilloscope 120 cannot be connected successfully, the IP address of the oscilloscope 120 needs to be input through the graphic user interface by the user.

When the control device 110 and the oscilloscope 120 are connected successfully, the measurement module 230 is used to measure the parameters of the LVDS signal, including setting the oscilloscope 120 to make it ready for measurement, measuring the signal parameters that the user is interested in and transmitting the measurement results to the test system 200. The measurement module 230 includes a setting module 232, a parameter measurement module 234 and a measurement result obtaining module 236. The setting module 232 is used to set the oscilloscope 120 for measurement, such as setting the persistence mode, the screen capture mod and the acquire mode, and selecting a measurement channel and so on. The parameter measurement module 234 is used to measure the LVDS signal parameters, such as the maximum positive peak voltage, the maximum negative peak voltage, peak-peak value, rise time, fall time and jitter etc. The measurement result obtaining module 236 is used to obtain the measurement results and the screen images including the waveform of the LVDS signal from the oscilloscope 120.

The assessment module 240 assesses whether the obtained parameters of the LVDS signal, such as the maximum positive peak voltage, the maximum negative peak voltage, peak-peak value, rise time, fall time, jitter and so on, of the LVDS signal 130 comply with relevant LVDS specifications set by the user. In one example, the LVDS specifications define a voltage range, such as a range 320 mv-520 mv for the maximum positive peak voltage reference. If the measured maximum positive peak voltage falls into the voltage range, the assessment module 240 may assess that the maximum positive peak voltage complies with the LVDS specifications set by the user.

The output module 250 outputs the parameters of the LVDS signal, such as the maximum positive peak voltage, the maximum negative peak voltage, peak-peak value, rise time, fall time, jitter and so on, of the LVDS signal 130 and the assessment result of the parameters from the assessment module 240 to the output device connected to the control device 110. In one embodiment, the output module 280 may output the maximum positive peak voltage, the maximum negative peak voltage, peak-peak value, rise time, fall time and jitter of the LVDS signal 130 and the assessment results from the assessment module 240using a graphic user interface for the user's reference during the engineering or mass production.

The report generating module 290 generates reports when all the measurements of all the parameters have been finished and the reports will be stored and put into a database for the user to search or read in later test procedures during the mass production or engineering. The content of the report may include all the measured parameters, the assessment result of the parameters, the specifications set by the user and the waveforms of the LVDS signal.

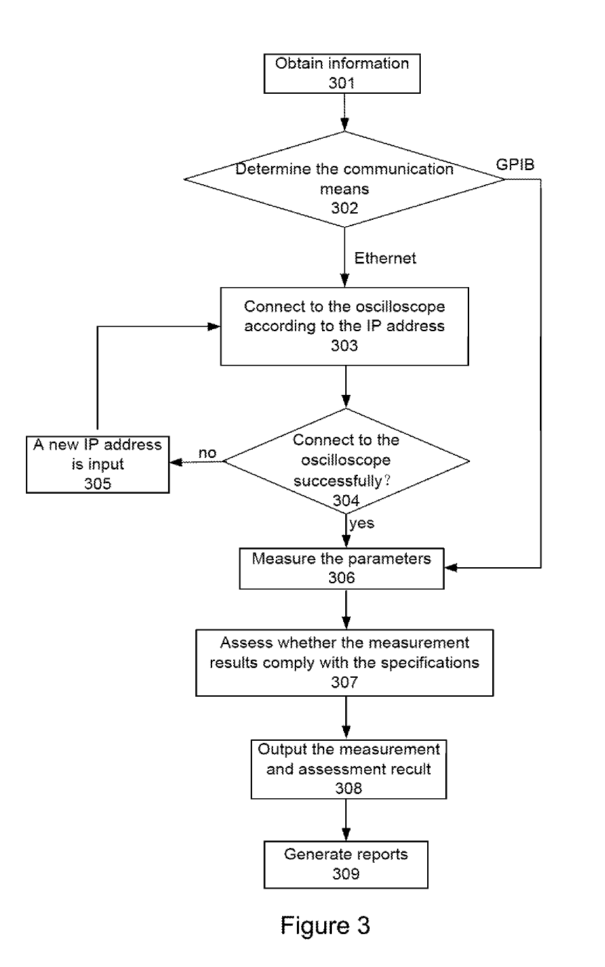

FIG. 3 is a flowchart of one embodiment of an LVDS test method according to one embodiment of the present invention. Depending on the embodiments, additional steps may be added, others removed, and the ordering of the steps may be changed.

In step 301, the input module 210 obtains the information needed by the test, such as the product number, the user name, the signal parameters that the user is interested in and the test specifications, through at least one graphic user interface for the user to input. In one embodiment, the graphic user interface also provides options for the user to select the communication means, such as Ethernet, General-Purpose Interface Bus (GPIB), to connect the control device 110 and the oscilloscope 120. If the user selects the communication means of Ethernet, the graphic user interface can be used for the user to input the IP address of the oscilloscope 120.

In step 302, the communication means selected by the user to connect the control device 110 and the oscilloscope 120 is determined. If the user selects the communication means of Ethernet, the communication module 220 firstly connects the control device 110 and the oscilloscope 120 using the IP address inputted by the user. In step 303, the control device 110 is connected to the oscilloscope 120 according to the IP address of the oscilloscope 120. In step 304, whether the oscilloscope 120 can be connected successfully by the IP address is determined. If the oscilloscope 120 fails to be connected successfully, the user needs to input the IP address of the oscilloscope 120 through the graphic user interface again in step 305 and the method returns to step 303, where the oscilloscope 120 is connected using the IP address newly input by the user. If the oscilloscope 120 is connected successfully in step 304, the method proceeds to step 306, where the parameters of the LVDS signal 130 are measured. Moreover, if it is determined that the communication means selected by the user is GPIB in step 302, then the method proceeds to step 306, where the parameters of the LVDS signal 130 are measured.

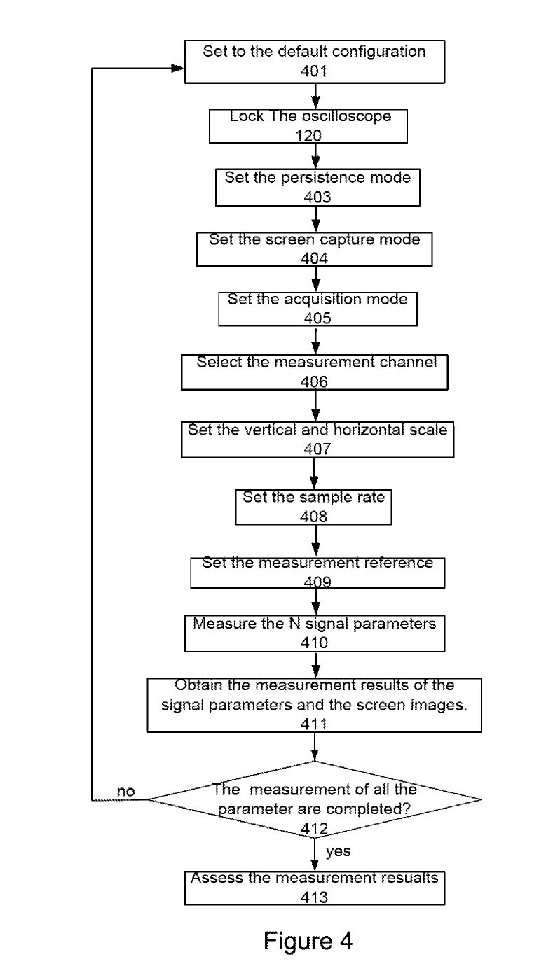

FIG. 4 is a flowchart of one embodiment of the parameter measurement step 306 in an LVDS test according to one embodiment of the present invention. In the measurement step, the parameters of the LVDS signal, such as the maximum positive peak voltage, the maximum negative peak voltage, peak-peak value, rise time, fall time, jitter and so on, can be measured. Depending on the embodiments, additional steps may be added, others removed, and the ordering of the steps may be changed.

In step 401, after the control device 110 is connected to the oscilloscope 120 successfully, the oscilloscope 120 is set to the default configuration, namely, the factory settings. Then in step 402, the oscilloscope 120 is locked to prevent any unwanted actions from the outside performed on the oscilloscope 120 when the test system 200 controls it. In step 403, the persistence mode is set for the oscilloscope 120. Persistence mode is the way for accumulated record points to be displayed, which includes infinite persistence mode, variable persistence mode, and no persistence mode. For example, in one embodiment, the persistence mode can be set to the infinite persistence mode.

Then in step 404, the screen capture mode is set, namely the format and style of the picture is set. The format and style of the picture determines the way in which the captured image displays and has nothing to do with the measurement result of the parameters. For example, in one embodiment, the style can be set to “colored, full-screen, jpg format”. The display format includes YT format, XY format and XYZ format. YT format shows the signal amplitude as it varies over time. XY format compare the amplitudes of the waveform records point by point. For example, channel 1 (X) and channel 2 (Y) can be compared. XYZ format can compare the voltage levels of the channel 1 (X) and channel 2 (Y) waveform records point by point as in XY format. The displayed waveform intensity is modulated by the Channel 3 (Z) waveform record. For example, in one embodiment, the display format can be set to YT format.

In step 405, the acquisition mode is set. Acquisition is the process of sampling an analog signal, converting it into digital data, and assembling it into a waveform record, which is then stored in acquisition memory. The acquisition mode includes Sample mode, Peak Detect mode, Hi Res mode, Envelope mode, Average mode and Waveform Database mode. Sample mode retains the first sampled point from each acquisition interval. Sample is the default mode. Peak Detect mode uses the highest and lowest of all the samples contained in two consecutive acquisition intervals. This mode only works with real-time, noninterpolated sampling and is useful for catching high frequency glitches. Hi Res mode calculates the average of all the samples for each acquisition interval. Hi-Res provides a higher-resolution, lower-bandwidth waveform. Envelope mode finds the highest and lowest record points over many acquisitions. Envelope uses Peak Detect for each individual acquisition. Average mode calculates the average value for each record point over many acquisitions. Average mode uses Sample mode for each individual acquisition. Average mode can be used to reduce random noise. Waveform Database mode is a three-dimensional accumulation of source waveform data over several acquisitions. In addition to amplitude and timing information, the database includes a count of the number of times a specific waveform point (time and amplitude) was acquired. For example, in one embodiment, the acquisition mode can be set to Sample mode.

In step 406, the measurement channel is selected. Each channel is equipped with a probe for obtaining signal data such as waveforms and so on. Then in step 407 the vertical and horizontal scale is set. And the horizontal sample rate is set in step 408. For example, in one embodiment, the measurement channel can be set to Channel 1; the vertical scale can be set to 125 mV/div; the horizontal scale can be set to 1 ns/div; the sample rate is set to 2.5 G/s.

In step 409, the measurement reference level is set. The reference level is used to measure rise time and fall time. For example, the time used for the signal to jump to the high level from the low level is the rise time. The time for the signal to jump from 10% of its amplitude to 90% of the amplitude or from 20% to 80% are typically used instead of the time from 0% to 100%. The user can select the reference level according to its specifications. The 10% to 90% mode is set by default. For example, in one embodiment, the measurement reference level is set to 20%-80%.

Next, in step 410 the N parameters of LVDS selected by the user are measured. When the measurement starts, the probe began to get LVDS waveform. When 500 waveforms are obtained, the measurement is stopped. In step 411, the measurement results and the screen images including waveforms are obtained from the oscilloscope in step 411. In one embodiment, for example, the maximum peak voltage, the maximum negative peak voltage, peak-peak value, rise time, fall time and jitter and other signal parameters are got by the collected 500 waveforms and obtained by the measurement result obtaining module 236 of the test system 200.

In step 412, it is determined whether all the parameters have been measured. For example, if the user switch off the oscilloscope 120 or forcefully terminate the measurement process, the parameter measurement may not be completed. If there is parameters that have not been measured, the method returns to step 401 to continue measuring the unfinished parameters. In step 412, if the measurement of all the parameters is finished, the measurement result is assessed.

Now returning to the flowchart of an LVDS test method shown in FIG. 3. After the measurement of all the parameters is finished, in step 307, whether the measured parameters, such as the maximum positive peak voltage, the maximum negative peak voltage, peak-peak value, rise time, fall time, jitter and so on comply with relevant LVDS specifications set by the user are assessed. In one example, the LVDS specifications define a voltage range, such as a range 320 mv-520 mv for the maximum positive peak voltage reference. If the measured maximum positive peak voltage falls into the voltage range, the assessment module 240 may assess that the maximum positive peak voltage complies with the LVDS specifications set by the user.

In step 308, the parameters of the LVDS signal, such as the maximum positive peak voltage, the maximum negative peak voltage, peak-peak value, rise time, fall time, jitter and so on, of the LVDS signal 130 and the assessment result of the parameters are output to the output device connected to the control device 110. In one embodiment, the maximum positive peak voltage, the maximum negative peak voltage, peak-peak value, rise time, fall time and jitter of the LVDS signal 130 and the assessment results may be output using a graphic user interface for the user's reference during the engineering or mass production.

In step 309, reports are generated when all the measurement of all the parameters have been finished and the reports will be stored and put into a database for the user to search or read in later test procedures during the mass production or engineering. The content of the report may include all the measured parameters, the assessment result of the parameters, the specifications set by the user and the waveforms of the LVDS signal.

Therefore, the test system and method for LVDS provided by the present invention can test the parameters of the LVDS signal quickly and efficiently. It can reduce the possibility of errors in measurement results caused by the operator's mistakes and shorten the average measuring time. Thus, the present invention can advantageously meet the competitive needs in fast mass production and efficient engineering qualification.

It should be appreciated that various modifications, adaptations and alternative embodiments thereof may be made within the scope and spirit of the present invention. The invention is further defined by the following claims.

What is claimed is:

1. A low voltage differential signaling (LVDS) test system, the system comprising:
an input module for the user to input the information needed by the test;
a communication module for connecting the control device and the oscilloscope using the communication means selected by the user;
a measurement module for measuring the parameters of the LVDS signal thought controlling a oscilloscope;
an assessment module for assessing whether the obtained parameters of the LVDS signal comply with relevant LVDS specifications; and
an output module for outputting the parameters of the LVDS signal and the assessment result of the parameters from the assessment module.

2. The system of claim 1 further comprises:
a report module for generating a report for the user to read when all the measurements of all the parameters have been finished.

3. The system of claim 2, wherein the measurement module comprises:
a setting module for setting the oscilloscope;
a parameter measurement module for measuring the LVDS signal parameters; and
a measurement result obtaining module for transmitting the measurement results of the LVDS signal from the oscilloscope to the test system.

4. The system of claim 3, wherein the setting module is further used for:
restoring the oscilloscope to the factory settings;
locking the oscilloscope;
setting the persistence mode;
setting the screen capture mode;
setting the acquisition mode;
selecting a measurement channel; and
setting the measurement reference level.

5. The system of claim 2, wherein the input module comprises a graphic user interface for the user to input the information needed by the test.

6. The system of claim 2, wherein the communication means is Ethernet or General-Purpose Interface Bus.

7. The system of claim 5, wherein the information needed by the test comprises the specifications the signal parameters to be tested.

8. The system of claim 7, wherein the signal parameters comprise the maximum positive peak voltage, the maximum negative peak voltage, peak-peak value, rise time, fall time and jitter.

9. The system of claim 2, wherein the oscilloscope is an oscilloscope for testing LVDS signals.

10. The system of claim 2, wherein the report further comprises obtained waveforms of the signals.

11. A low voltage differential signaling test method, the method comprising:
obtaining the information needed by the test;
connecting the control device and the oscilloscope using the communication means selected by the user;
measuring the parameters of the LVDS signal thought controlling a oscilloscope;
assessing whether the obtained parameters of the LVDS signal comply with relevant LVDS specifications; and
outputting the parameters of the LVDS signal and the assessment result of the parameters from the assessment module.

12. The method of claim 11 further comprises:
generating a report for the user to read when all the measurements of all the parameters have been finished.

13. The method of claim 12, wherein the measuring the parameters of the LVDS signal thought controlling an oscilloscope comprises:
setting the oscilloscope;
measuring the LVDS signal parameters; and
transmitting the measurement results of the LVDS signal from the oscilloscope to the test system.

14. The method of claim 12, wherein the setting the oscilloscope comprises:
restoring the oscilloscope to the factory settings;
locking the oscilloscope;
setting the persistence mode;
setting the screen capture mode;
setting the acquisition mode;
selecting a measurement channel; and
setting the measurement reference level.

15. The method of claim 12, wherein the obtaining the information needed by the test comprises obtaining the information needed by the test through a graphic user interface.

16. The method of claim 12, wherein the communication means is Ethernet or General-Purpose Interface Bus.

17. The method of claim 15, wherein the information needed by the test comprises the specifications the signal parameters to be tested.

18. The method of claim 17, wherein the signal parameters comprise the maximum positive peak voltage, the maximum negative peak voltage, peak-peak value, rise time, fall time and jitter.

19. The method of claim 12, wherein the oscilloscope is an oscilloscope for testing LVDS signals.

20. The method of claim 12, wherein the report further comprises obtained waveforms of the signals.
